(19) United States
(12) Patent Application Publication
(10) Pub. No.: US 2023/0422633 A1
(43) Pub. Date: Dec. 28, 2023

(54) METHOD OF FORMING A THIN FILM

(71) Applicant: Microsoft Technology Licensing, LLC, Redmond, WA (US)

(72) Inventors: Keita Otani, (DK); Peter Krogstrup Jeppesen, (NL)

(73) Assignee: Microsoft Technology Licensing, LLC, Redmond, WA (US)

(21) Appl. No.: 18/039,202

(22) PCT Filed: Dec. 4, 2020
(86) PCT No.: PCT/EP2020/084618

§ 371 Date: May 26, 2023

(51) Int. Cl. H10N 60/01; H10N 60/12; H10N 60/85; H10N 60/81

(52) U.S. Cl. CPC H10N 60/0912; H10N 60/12; H10N 60/855; H10N 60/815

(57) ABSTRACT

A method of forming a thin film of material on a surface of a substrate, the substrate comprising a semiconductor, comprises: depositing a thin film of metal on the surface of the substrate, wherein the deposition is performed in an ultra-high vacuum, and wherein the substrate is at a temperature of less than or equal to 260 K during the deposition. Cooling the substrate during deposition of the thin film of metal may allow for an atomically flat and very uniform thin film to be obtained. Also provided is a device obtainable by the method.

### BACKGROUND

The fabrication of various types of electronic components involves forming a stack of metal and metal oxide layers. One example of such a component is a Josephson junction. Josephson junctions are one of the fundamental components needed for constructing superconducting quantum computing devices.

A Josephson junction comprises a pair of superconductive electrodes which are spaced from one another by a non-superconductive “weak link”. The weak link is configured to allow a supercurrent to flow between the two superconductors by quantum tunnelling. The weak link may comprise an oxide barrier.

A further example of an electronic component which includes a stack of metal and metal oxide layers is a field effect transistor, FET. An FET comprises a source electrode, a drain electrode, a channel of semiconductor material, a gate electrode for applying an electrostatic field to the channel, and a gate dielectric arranged between the gate electrode and the channel. The gate electrode and gate dielectric may be referred to collectively as a gate stack. The gate dielectric may comprise a metal oxide layer. FETs are useful in many conventional electronic devices.

### SUMMARY

In one aspect, there is provided a method of forming a thin film of material on a surface of a substrate, the substrate comprising a semiconductor, which method comprises: depositing a thin film of metal on the surface of the substrate; wherein the deposition is performed in an ultra-high vacuum; and wherein the substrate is at a temperature of less than or equal to 260 K during the deposition. It has been found that cooling the substrate during deposition of the thin film of metal may allow for an atomically flat and very uniform thin film to be obtained.

In another aspect, there is provided a device, comprising: a plurality of thin films of metal and a plurality of layers of an oxide of the metal, wherein the thin films and the layers are arranged in an alternating stack. This structure may have improved superconductor properties in comparison with a singular film of the metal.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a flow chart outlining an example method;

FIG. 2 is a simplified block diagram of an example apparatus useful for implementing the method;

FIG. 3 is a schematic cross-sectional diagram of an example Josephson junction structure obtainable using a method of the present disclosure;

FIG. 4 is a schematic cross-sectional diagram of a field-effect transistor obtainable using a method of the present disclosure;

FIG. 5 is an atomic force microscopy, AFM, micrograph of the surface of a first aluminium oxide layer formed using the method of the present disclosure;

FIG. 6 is an AFM micrograph of the surface of a top aluminium oxide layer of a stack of aluminium and aluminium oxide layers formed using the method of the present disclosure;

FIG. 7 is a transmission electron microscopy, TEM, micrograph of a stack of aluminium and aluminium oxide layers formed on a substrate using the method of the present disclosure;

FIG. 8a is a transmission electron microscopy, TEM, micrograph of an example device including a layer of aluminium oxide formed on III-V semiconductor nanowire facet using the method of the present disclosure;

FIG. 8b is an energy-dispersive X-ray spectroscopy, EDX, micrograph of the FIG. 8a device;

FIG. 9 shows the relationship between source-drain conductance and gate for an example field effect transistor fabricated using the method of the present disclosure; and

FIG. 10 shows a plot of resistance against temperature for: (a) a single layer of aluminium; and (b) a structure having two layers of aluminium separated by an aluminium oxide layer obtained by the method of the present disclosure.

### DETAILED DESCRIPTION

As used herein, the verb ‘to comprise’ is used as shorthand for ‘to include or to consist of’. In other words, although the verb ‘to comprise’ is intended to be an open term, the replacement of this term with the closed term ‘to consist of’ is explicitly contemplated, particularly where used in connection with chemical compositions.

A “nanowire” is an elongate member having a nano-scale width, and a length-to-width ratio of at least 100, or at least 500, or at least 1000. A typical example of a nanowire has a width in the range 10 to 500 nm, optionally 50 to 100 nm or 75 to 125 nm. Lengths are typically of the order of micrometres, e.g. at least 1 μm, or at least 10 μm.

A “semiconductor-superconductor hybrid structure” comprises a semiconductor component and a superconductor component, and configured to allow energy level hybridisation between the semiconductor and superconductor under certain operating conditions. In particular, this term refers to a structure capable of showing topological behaviour such as Majorana zero modes, or other excitations useful for quantum computing applications. The operating conditions generally comprise cooling the structure to a temperature below the critical temperature, Tc, of the superconductor component, applying a magnetic field to the structure, and applying electrostatic gating to the structure. Generally, at least part of the semiconductor component is in intimate contact with the superconductor component. For example, the superconductor component may be epitaxially grown on the semiconductor component.

An “ultra-high vacuum” is an environment having a pressure of less than or equal to 100 nanopascal.

A “thin film” is a continuous layer of material having a thickness of less than or equal to 10 μm, in particular, a continuous layer of material having a thickness of less than or equal to 100 nm. A thin film includes at least a monolayer of atoms.

“Room temperature” is a temperature in the range 18 to 24° C.

The term “about” where used in connection with a numeral contemplates a variance of ±10%.

Josephson junctions based on an aluminium/aluminium oxide layer stack have been described. Previous approaches to fabricating Josephson junctions have involved room temperature film deposition and oxidation. It has been found that layers fabricated under such conditions are not crystalline, and that the surfaces of the layers are not atomically flat. This degrades the quality of the interfaces between layers in the stack. The interface quality is believed to limit device performance and reliability.

Provided herein is a method of fabricating a thin film of material which may have improved surface properties. The present method may be useful for fabricating Josephson junctions, as well as other components such as FETs.

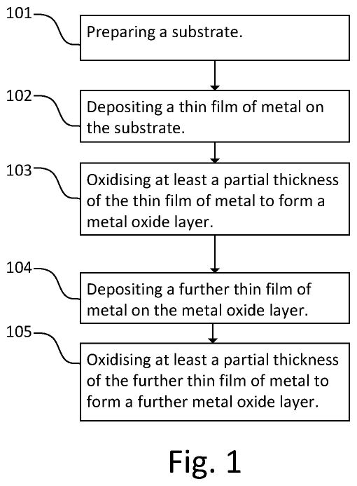

An example method will now be described with reference to FIG. 1. FIG. 1 is a flow chart outlining the method.

At block 101, a substrate is prepared.

The substrate may comprise a wafer of semiconductor material. A wafer is a single crystalline piece of material.

The nature of the semiconductor material is not particularly limited. A wide variety of semiconductor materials may be used. Illustrative examples of semiconductor materials include indium phosphide, gallium arsenide, indium antimonide, indium arsenide, gallium antimonide, silicon, and germanium.

For example, the semiconductor material may be a III-V semiconductor. A III-V semiconductor is an alloy including at least one group III element selected from aluminium, gallium, and indium; and at least one group V element selected from nitrogen, phosphorous, arsenic, and antimony. The alloy may be a binary, ternary, or quaternary alloy.

More specific examples of III-V semiconductors include alloys of Formula 1:

InAsₓSb₁₋ₓ (Formula 1)

where x is in the range 0 to 1. In other words, the semiconductor material may comprise indium antimonide (x=0), indium arsenide (x=1), or a ternary mixture comprising 50% indium on a molar basis and variable proportions of arsenic and antimony (0<x<1). Materials of Formula 1 have been found to have particularly good lattice matching with aluminium.

Further examples of semiconductor materials are the II-VI semiconductors. Examples of II-VI semiconductor materials include lead telluride and tin telluride.

The wafer may have a planar surface. Alternatively, the surface of the wafer may include one or more steps, mesas, and/or trenches. If desired, one or more regions of the wafer may be doped.

Preparing the substrate may comprise placing the wafer in an appropriate apparatus, such as apparatus 200 described below.

Preparing the substrate may additionally comprise fabricating a semiconductor component on the wafer. In such implementations, the semiconductor component may be epitaxially grown on the wafer, for example by selective area growth. Selective area growth makes use of a mask in combination with a deposition technique such as molecular beam epitaxy to grow a semiconductor component at a desired position defined by an opening in the mask. The semiconductor component may be in the form of a nanowire.

Typically, the wafer and semiconductor component comprise different materials. The material the wafer may have a larger band gap than the material of the semiconductor component. In one example, the wafer comprises indium phosphide and the semiconductor component comprises a material of Formula 1.

In some implementations, a buffer layer may be formed on the surface of the wafer and the semiconductor component may subsequently be grown on the buffer layer.

The buffer layer may be a layer of a semiconductor material different from that of the substrate and the semiconductor component. The material of the buffer layer may be selected to have a lattice constant which is between the lattice constant of the wafer and the lattice constant of the semiconductor component. This may allow the semiconductor component to be grown more easily.

In an example, the wafer comprises indium phosphide, the semiconductor component comprises a material of Formula 1, and the buffer layer comprises a material of Formula 2:

In_{z}Ga_{1-z}As (Formula 2)

where z is in the range 0.01 to 0.5, optionally about 0.2. The material of Formula 1 may be indium arsenide.

As used herein, the term “substrate” may refer to the wafer and any semiconductor component(s) on the surface of the wafer. The substrate may further include further components, such as a layer of mask material, particularly in implementations where selective area growth is used in the fabrication of the semiconductor component.

At block 102, a thin film of metal is deposited on the surface of the substrate. The metal may be selected from aluminium and tantalum. These metals have been investigated in particular. It is believed that the present method may be applicable to any metal which is compatible with molecular beam epitaxy.

During the deposition, the substrate is at a temperature of less than or equal to 260 K, e.g. a temperature in the range 77 K to 260 K. For example, the substrate may be in contact with a cold finger of an appropriate cooling plate. The cold finger may be liquid-nitrogen cooled.

The cold finger may have a temperature in the range 77 to 150 K, optionally 110 to 130 K, further optionally 115 to 125 K, or about 120 K. Cold finger temperatures in these ranges have been found to be particularly useful for the deposition of aluminium.

The deposition is performed in an ultra-high vacuum, in other words, in an environment having a pressure of less than or equal to 100 nanopascals. In particular, the deposition may be performed in an environment having a pressure of less than or equal to 10 nanopascals.

The deposition may comprise molecular beam epitaxy or evaporation. These techniques may allow for precise control over the thickness of the film of metal.

The thickness of the metal film may be selected as desired, depending on the nature of the device to be fabricated. For example, the thickness may be in the range 0.2 to 10 nm, optionally 0.2 to 5 nm, further optionally 0.2 to 3 nm.

It has been found that, by depositing the metal onto a cold substrate in an ultra-high vacuum, a thin film having a clean and atomically flat surface may be obtained.

Without wishing to be bound by theory, it is believed that at temperatures below 260 K and in an ultra-high vacuum, aluminium exhibits a different crystal growth mechanism to the mechanism which occurs when using a conventional technique at room temperature. At room temperature, large, widely spaced crystal grains are formed. At temperatures below 260 K, the crystal grains obtained are small and closely spaced. This allows the crystal grains to merge together into a thin film at the end of the growth process. This results in improvements in flatness and degree of crystallinity.

Tantalum has been found to behave differently to aluminium under these conditions. Tantalum layers obtained using the present methods are atomically flat and uniform, but are less crystalline and may be amorphous. It is believed that when tantalum hits the substrate, it tends to stick without migrating across the surface of the substrate.

Depending on the nature of the device to be fabricated, the method may be stopped after block 102, or may continue to block 103.

At block 103, at least a partial thickness of the thin film of metal is oxidised to form a layer of metal oxide.

The oxidation may comprise exposing the thin film of metal to oxygen gas. The oxygen gas may be at a pressure in the range in the range 0.1 to 10 Pa, e.g. 0.5 to 1.5 Pa. In implementations where the metal is aluminium, exposing the metal to oxygen gas having a pressure of about 1 Pa provides a convenient way to perform the oxidation. Oxidation of aluminium under these conditions takes about 5 minutes.

The cooling of the substrate is stopped before the oxidation, for example by removing the substrate from the cooling plate. The oxidation may be performed at a temperature greater than or equal to 0° C., for example in the range 0 to 30° C., or at room temperature. In implementations where the metal is tantalum, it may be desirable to heat the thin film of metal during the oxidation, e.g. to a temperature in the range 50 to 350° C.

The oxidation may be complete oxidation, in other words substantially all of the metal may be converted to its oxide. Alternatively, the oxidation may be incomplete: an upper portion of the thin film of metal may be converted to oxide, and a lower portion of the thin film of metal may remain as metal.

The extent of the oxidation may be controlled by selecting the thickness of the thin film of metal appropriately, and/or by varying the conditions used for the oxidation. For example, aluminium will spontaneously oxidise to a depth of about 3 nm when exposed to oxygen gas.

It has been found that, when partial oxidation is performed, a very smooth interface between the metal and metal oxide is obtained.

The method may terminate after block 103, or may continue to block 104 depending on the nature of the device to be fabricated.

At block 104, a further thin film of metal is deposited on the metal oxide layer obtained at the previous step.

The operations performed at block 104 differ from those described at block 102 in that the thin film of metal is deposited on the metal oxide layer which was obtained at block 103.

The metal which is deposited may be the same as the metal deposited at block 102, or may be a different metal.

The method may then terminate, or may progress to block 105. Block 105 comprises repeating the oxidation step described at block 103, this time on the further thin film of metal obtained at block 104. The oxidation may comprise fully oxidizing the further thin film of metal, which effectively increases the thickness of the oxide layer obtained at block 103.

The operations of blocks 104 and 105 may be repeated as desired. There is no particular upper limit on the number of repetitions, because layers having consistent surface properties are obtained.

A multi-layered stack of aluminium/aluminium oxide films has surprisingly been found to have advantageous superconductor properties compared to a stack having a single layer of aluminium and a single layer of aluminium oxide. As illustrated in Example 4, the multi-layered stack has been found to have a relatively high superconductor transition temperature.

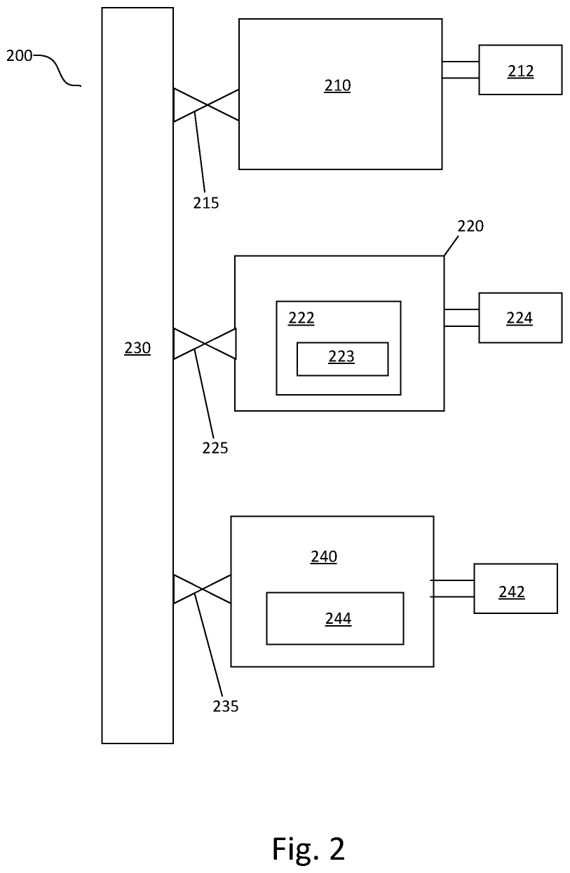

FIG. 2 is a block diagram of an example apparatus 200 useful for implementing the method. The apparatus 200 includes a set of vacuum chambers 210, 220, 240 for performing the various operations described with reference to FIG. 1. These chambers may be collectively referred to as working chambers. The working chambers are all connected to a shared buffer chamber 230 via respective valves 215, 225, 235. This apparatus may allow the various operations described with reference to FIG. 1 to be performed conveniently without exposing the workpiece to the atmosphere. Any other appropriate apparatus may alternatively be used to implement the method. For example, the described operations may be performed in separate apparatuses.

The first vacuum chamber 210 is a vacuum chamber for semiconductor component fabrication. Chamber 210 is configured to allow fabrication of a semiconductor component on a wafer, as described above with reference to block 101 of FIG. 1. To this end, semiconductor fabrication vacuum chamber 210 is in communication with a material source 212 for providing semiconductor material, or a suitable precursor thereof, for deposition on the wafer.

First vacuum chamber 210 is coupled to the buffer chamber 230 via a first gate valve 215.

A second vacuum chamber 220 for metal film deposition is coupled to the buffer chamber 230 via a second gate valve 225. The second vacuum chamber is configured to allow deposition of a thin film of metal, as described with reference to block 102 of FIG. 1. Second vacuum chamber 220 is configured to provide an ultra-high vacuum environment. A cooling plate 222 having a cold finger 223 is arranged in the second vacuum chamber 220. The cold finger of the cooling plate 222 may be liquid-nitrogen cooled.

The second vacuum chamber 220 is in communication with a metal source 224 for providing a flux of metal atoms or ions to be deposited on the substrate. Metal source 224 may, for example, comprise a molecular beam epitaxy cell. The purity of the metal is preferably as high as possible.

A third vacuum chamber 240 is also coupled to buffer chamber 230 via a third gate valve 235. The third vacuum chamber 230 is configured to allow for oxidation of the thin film of metal as described with reference to block 103 of FIG. 1, and may be referred to as an oxidation chamber. The third vacuum chamber is connected to an oxygen gas supply 242. The third vacuum chamber and oxygen gas supply 242 may together be configured to provide an environment having an oxygen gas pressure of 0.1 to 10 pascals, optionally 0.5 to 5 pascals.

The third vacuum chamber 240 may include a heating element 244 for heating the thin film of metal.

As described, each of the working chambers is connected to the buffer chamber 230. The buffer chamber 230 is a further vacuum chamber. Workpieces may therefore be transferred between the working chambers without exposing the workpieces to the open atmosphere.

By connecting working chambers via a buffer chamber rather than direct connections, the unwanted transfer of reagents between the working chambers may be prevented. In particular, it may be desirable to prevent the oxygen gas used in the third vacuum chamber 240 from entering the second vacuum chamber 220. To this end, the buffer chamber 230 and the gate valves 215, 225, 235 are operable as an airlock.

In use, only one of gate valves 215, 225, 235 will be opened at any given time when transferring the workpiece from one chamber to the next chamber. Buffer chamber 230 may be provided with an entry valve for allowing a wafer to be inserted into the apparatus, and to allow the finished product to be removed from the apparatus.

Various modifications may be made to the apparatus 200.

The first vacuum chamber 210 may be omitted.

Buffer chamber 230 may be omitted. In such implementations, working chambers may be connected in series, e.g. by gate valves.

Other apparatuses may be used to implement the present methods, and in principle all stages of the methods could be implemented in a single vacuum chamber.

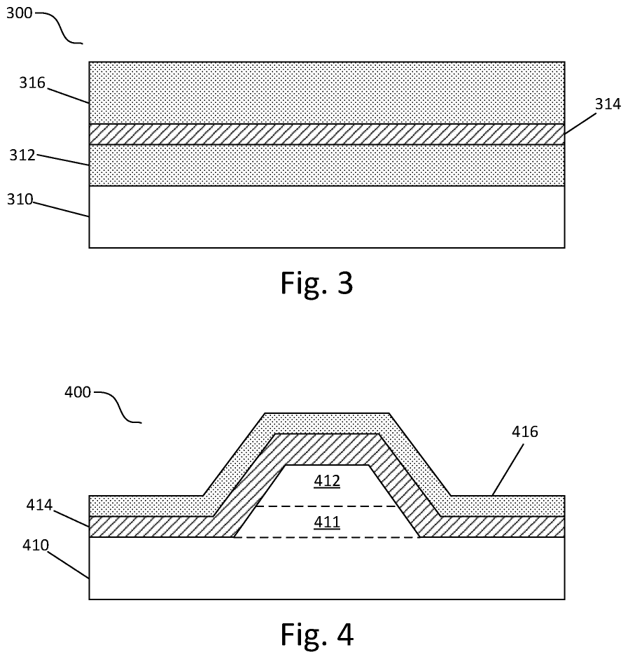

A first example of a structure 300 obtainable by the method of the present disclosure is illustrated in FIG. 3.

The structure 300 includes a substrate 310, which in this example consists of a wafer of semiconducting material. A first epitaxial thin film of metal 312 is arranged on the surface of substrate 310.

A metal oxide layer 314 is arranged on the epitaxial thin film of metal 312. The arrangement of metal 312 and metal oxide 314 is obtainable by depositing a thin film of metal and then performing a partial oxidation of the thin film of metal, as described with reference to blocks 102 and 103 of FIG. 1.

A second thin film of metal 316 is arranged on the metal oxide layer 314. The second thin film of metal is obtainable by performing the operations of block 104 of FIG. 1. A further oxide layer may be formed from the second thin film of metal, if desired.

The structure 300 illustrated in FIG. 3 may be useful as a Josephson Junction, with the first and second thin films of metal 312, 316 corresponding to superconducting electrodes of the Josephson Junction, and metal oxide layer 314 providing a weak link between the electrodes.

Alternatively, the structure 300 may be useful as a capacitor, with the first and second thin films of metal 312, 316 corresponding to plates of the capacitor, and metal oxide layer 314 providing a dielectric between the plates. In such implementations, the metal may be tantalum.

A second example of a structure 400 obtainable by a method of the present disclosure is illustrated in FIG. 4.

The structure 400 includes a substrate comprising a wafer of semiconducting material 410. An epitaxially-grown buffer layer 411 is arranged on the wafer, and an epitaxially-grown semiconductor component 412 is arranged on the buffer layer 411. The buffer layer 411 and semiconductor component 412 may be fabricated by selective area growth, and may be in the form of nanowires. Wafer 410, buffer layer 411 and semiconductor component 412 comprise different materials, with the semiconductor component 412 having a smaller band gap than the wafer 410, and the material of buffer layer 411 having a lattice constant which is between the lattice constant of the wafer 410 and the semiconductor component 412.

A thin film of metal oxide 414 is arranged on the substrate 410, 412. Thin film 414 is obtainable by depositing a thin film of metal, and then fully oxidising the thin film of metal. Depending on the desired thickness of the thin film of metal oxide, the thin film of metal oxide may be built up in stages. A thin film of metal may be deposited and then fully oxidized, and then then these steps may be repeated until a layer of metal oxide of the desired thickness is obtained. For example, to form one metal oxide layer, deposition and complete oxidation may be repeated 2 to 12 times, optionally 7 to 9 times, further optionally 8 times.

A thin film of metal 416 is arranged on the thin film of metal oxide 414. The thin film of metal 416 is obtainable by performing the operations of block 104 of FIG. 1.

To form a FET comprising the example structure 400, opposing ends of the semiconductor component 412 may be connected to source and drain electrodes, respectively. Semiconductor component 412 may then act as the channel of the FET, with the thin film of metal oxide 414 and the thin film of metal 416 serving as the gate stack of the FET. Buffer layer 411 is not essential to the operation of the device, and may be omitted if desired.

In an alternative implementation of a FET, epitaxially-grown semiconductor component 412 is replaced by a doped region of the wafer.

Since the present methods allow high quality interfaces between the semiconductor, oxide layer, and metal film to be obtained, charge trapping by metal oxide layer 414 may be reduced. This may allow for the fabrication of a FET having improved operating characteristics.

To modify structure 400 to obtain instead a semiconductor-superconductor hybrid structure, the material used as semiconductor component 412 may be selected to allow for energy level hybridisation with the chosen metal. For example, the semiconductor component may comprise a material of Formula 1, and the metal may be aluminium. Further, the order of the metal layer and metal oxide layer is reversed, such that the metal layer is in contact with the semiconductor component. This may be implemented by performing a single deposition, and a partial oxidation of the deposited layer. High-quality interfaces are especially important for semiconductor-superconductor hybrid structures, since a poor interface may prevent the desired quantum mechanical interactions in such a device.

The example structures are illustrative, and the methods provided herein may be applied to the fabrication of other devices having a metal or metal oxide thin film arranged on a semiconductor, in particular those having an alternating stack of metal thin films and metal oxide thin films.

It will be appreciated that the above embodiments have been described by way of example only.

More generally, there is provided a method of forming a thin film of material on a surface of a substrate, the substrate comprising a semiconductor, which method comprises: depositing a thin film of metal on the surface of the substrate; wherein the deposition is performed in an ultra-high vacuum; and wherein the substrate is at a temperature of less than 260 K during the deposition. It has been found that cooling the substrate during deposition of the thin film of metal allows for an atomically flat and very uniform thin film to be obtained.

The nature of the metal is not particularly limited, provided that a thin film of the metal can be obtained by deposition in an ultra-high vacuum. In particular, the metal may be selected from aluminium and tantalum. Aluminium may be particularly preferred. It has been found that aluminium forms small, closely-spaced crystal grains when deposited onto a cold substrate, which then merge together as crystal growth progresses. A flat and highly crystalline thin film may be obtained when using aluminium.

The thin film of metal may be deposited using a process selected from molecular beam epitaxy and evaporation. These techniques allow for a good level of control over the thickness of the thin film. Molecular beam epitaxy has been investigated in particular.

The ultra-high vacuum may be an environment having a pressure of less than or equal to 10 Pa. By minimizing the pressure, cleaner interfaces between layers may be obtained.

The substrate may be in contact with a cold finger during the deposition. The cold finger may be at a temperature in the range 77 to 150 K, optionally 110 to 130 K, and further optionally in the range 120 to 130 K. This temperature range is particularly useful in implementations where the metal is aluminium.

The method may further comprise, after the deposition, oxidising at least a partial thickness of the thin film of metal to form a metal oxide layer. The methods provided herein may be used to form a thin layer of metal, a thin layer of metal oxide, or both.

The oxidation may comprise fully oxidising the thin film of metal. This may be desirable in implementations where the thin film of material is to act as a dielectric. For example, the method may be useful for fabricating the gate dielectric of a field-effect transistor.

Alternatively, the oxidation may comprise partial oxidation. This may be useful in implementations where it is desired to fabricate both a thin film of metal and a thin film of metal oxide.

The oxidation may comprise exposing the thin film of metal to oxygen gas. The oxygen gas may be at a pressure in the range 0.1 to 10 Pa, for example 0.5 to 1.5 Pa. It has been found that exposing an aluminium layer to oxygen gas at pressures in this range forms an aluminium oxide thin film having good uniformity within about 5 minutes.

In implementations where the metal is aluminium, the exposure may be performed below room temperature (25±5° C.). The substrate is typically not in contact with the cold finger during the oxidation. The exposure may be performed directly after forming the thin film of metal and removing the substrate from contact with the cold finger, without necessarily bringing the substrate up to room temperature.

In implementations where the metal is tantalum, the oxidation may further comprise heating the thin film of tantalum to a temperature in the range 50 to 350° C. in the presence of the oxygen gas.

The extent of the oxidation may be controlled by selecting the thickness of the thin film of metal and/or by adjusting the oxidation conditions, such as temperature and pressure. For example, aluminium will spontaneously oxidise to a depth of about 3 nm when exposed to oxygen gas.

The method may further comprise, after the oxidation, performing a further deposition to form a further thin film of metal on the metal oxide layer, wherein the further deposition is performed in an ultra-high vacuum; and wherein the substrate is at a temperature of less than 260 K during the further deposition. Depositing more than one metal layer may be desirable for fabricating certain devices or components.

For example, in implementations where the oxidation is partial oxidation, a further thin film of metal may be deposited to form a Josephson junction structure. In implementations where the oxidation is complete oxidation, a further thin film of metal may represent a gate electrode of a field effect transistor.

The method may further comprise, after the further deposition, performing a further oxidation to form a further metal oxide layer. The present methods allow for the fabrication of stacks of layers. The deposition and oxidation steps may be repeated any number of times to obtain the desired stack of layers.

The metal used for each deposition may be the same metal; or may be independently selected.

The or each deposition may be performed in a deposition vacuum chamber, and the or each oxidation may be performed in an oxidation vacuum chamber, the deposition vacuum chamber and oxidation vacuum chamber being coupled to a buffer chamber via respective valves. The method further comprises transferring the substrate between the deposition vacuum chamber to the oxidation vacuum chamber via the buffer chamber. In this way, exposure of the substrate to the atmosphere may be avoided during the method. This may in turn help to maintain the quality of the layers and interfaces between layers.

The substrate may comprise a wafer of semiconductor material. The method further comprises, before the deposition, fabricating a semiconductor component on the wafer. Fabricating the semiconductor component may comprise growing the semiconductor component using molecular beam epitaxy. For example, the semiconductor component may be fabricated using selective area growth.

The semiconductor component may be fabricated in a semiconductor fabrication vacuum chamber, coupled to the deposition vacuum chamber via a valve. This may allow exposure of the substrate to the atmosphere to be avoided.

The substrate may comprise a material of Formula 1:

InAsₓSb₁₋ₓ (Formula 1)

where x is in the range 0 to 1. For example, the substrate may comprise indium arsenide. Materials of Formula 1 have particularly good compatibility with aluminium, for example good lattice matching.

In implementations where the substrate comprises a material of Formula 1, the surface of the substrate may be a {100} crystal face, a {111} crystal face, or a {110} crystal face.

Another aspect provides a device obtainable by the method.

The device may comprise: a plurality of thin films of metal; and a plurality of layers of an oxide of the metal; wherein the thin films and the layers are arranged in an alternating stack. By “alternating stack” is meant a sandwich structure in which each thin film is separated from the next by an oxide layer, and each oxide layer is separated from the next by a thin film. Layers and films may be in direct contact, with no further components arranged between the layers and films.

The metal may be aluminium. It has been found that an alternating stack of aluminium films and aluminium oxide layers may have favourable superconductor properties, in particular an increased critical temperature, compared to a singular thin film of aluminium.

The device may further comprise a semiconductor component, wherein the alternating stack is arranged on the semiconductor component. The semiconductor component may comprise a material of Formula 1, as defined hereinabove. The semiconductor component may be arranged on a wafer of semiconductor material. The alternating stack may be particularly useful in Josephson junctions, field-effect transistors, and semiconductor-superconductor hybrid devices, for example.

The thin films and the layers have a root-mean-square surface roughness in the range 0.1 nm to 0.4 nm.

Root-mean-square surface roughness, commonly abbreviated as R^{q}, may be measured using atomic force microscopy and then processing the atomic force microscopy data. The atomic force microscopy may comprise scanning an area of 10 μm². The resolution of the scan may be 1024 lines, with 1024 samples per line. Any probe suitable for measuring an R^{q} within the stated range may be used. For example, the probe may have a triangular tip with a radius in the range 2 to 12 nm. An example probe is available from Bruker under the trade name “ScanAsyst-Air”. Any suitable data processing software may be used to calculate R^{q}, and it is believed that all calculation methods should give the same result to within ordinary experimental uncertainty.

### Example 1

An indium arsenide, InAs, wafer having a surface comprising a (100) crystal face was prepared. The wafer was placed on a cooling plate in the vacuum chamber of a molecular beam epitaxy apparatus, with the wafer being in contact with a cold finger. A thin film of aluminium was then grown on the surface of the wafer.

The cold finger was cooled to a temperature of approximately 120 K using liquid nitrogen. The pressure in the vacuum chamber during growth of the thin film was 10 nanopascals. The aluminium was delivered from a cell of high-purity aluminium.

After growing the thin film of aluminium, the substrate was transferred from the vacuum chamber to a buffer chamber, and then from the buffer chamber to an oxidation chamber. Oxygen gas at a pressure of about 1 pascal was added to the oxidation chamber. The thin film of aluminium was exposed to the oxygen gas for about 5 minutes.

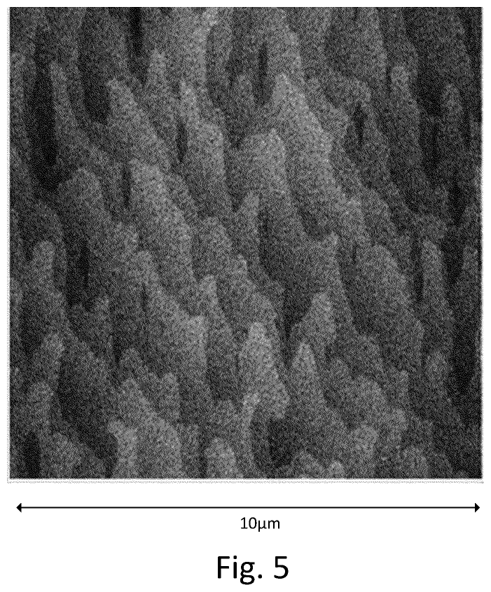

An atomic force microscopy image of the surface of the resulting aluminium oxide layer was collected. This image is shown in FIG. 5. The aluminium oxide layer was observed to have a step height which corresponds to the atomic step higher of a (100) indium arsenide crystal face. The root mean square surface roughness, as measured by atomic force microscopy in conjunction with image processing software, was 0.29 nm. The atomic force microscopy was performed using a Bruker Dimension Icon atomic force microscope, operating in ScanAsyst-air mode. The following operating parameters were used:
Scan area: 10 μm²,
Scan Speed: 0.988 Hz
Sampling per line: 1024
Lines: 1024
Scan Auto Control enabled.

A second thin film of aluminium was then grown on the aluminium oxide layer, under the same conditions as those used to grow the first thin film. The second thin film was then exposed to oxygen gas, to form a second aluminium oxide layer.

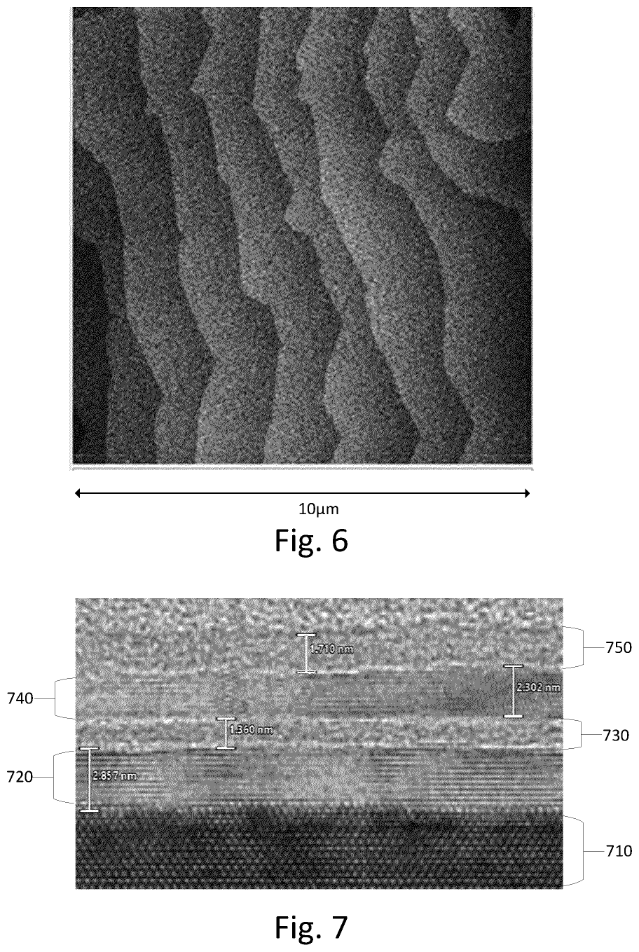

The resulting structure was investigated by atomic force microscopy, and the results are shown in FIG. 6. As may be seen, the atomic steps of the indium arsenide are still visible after forming the second aluminium layer and the second aluminium oxide layer. The root mean square surface roughness was 0.32 nm, which is almost same as that of the first aluminium oxide layer. This demonstrates that multiple smooth layers may be formed using the present techniques.

The smoothness of the layers obtained using the present method are further illustrated in FIG. 7. FIG. 7 is a transmission electron microscopy image of the double layer stack of AlOx/Al. The image shows, from bottom to top, the indium arsenide substrate 710; a first aluminium layer 720 having a thickness of 2.857 nm; a first aluminium oxide layer 730 having a thickness of 1.360 nm; a second aluminium layer 740 having a thickness of 2.302 nm; and a second aluminium oxide layer 750 having a thickness of 1.710 nm. The image demonstrates that well-defined layers with very smooth interfaces were achieved.

### Example 2

A device of the type described with reference to FIG. 4 was fabricated using a method according to the present disclosure, and subsequently investigated using transmission electron microscopy.

An indium phosphide substrate was used as the wafer. A buffer layer of In_{0.2}Ga_{0.8}As having a thickness of approximately 50 nm was grown on the wafer. Subsequently, an indium arsenide nanowire was grown on the buffer layer. The buffer layer and nanowire together had a height of approximately 140 nm measured with respect to the surface of the substrate, and a width at the surface of the substrate of about 210 nm.

A thin film of aluminium was deposited over the resulting structure. During the deposition, the wafer was in contact with a cold finger having a temperature of 130 K.

Subsequently, the thin film of aluminium was partially oxidized by contacting the thin film with oxygen gas to form aluminium oxide layer 820.

In order to prevent damage to the structure by transmission electron microscopy, a protective layer 830 of silicon dioxide, SiO₂, was then formed over the aluminium oxide layer.

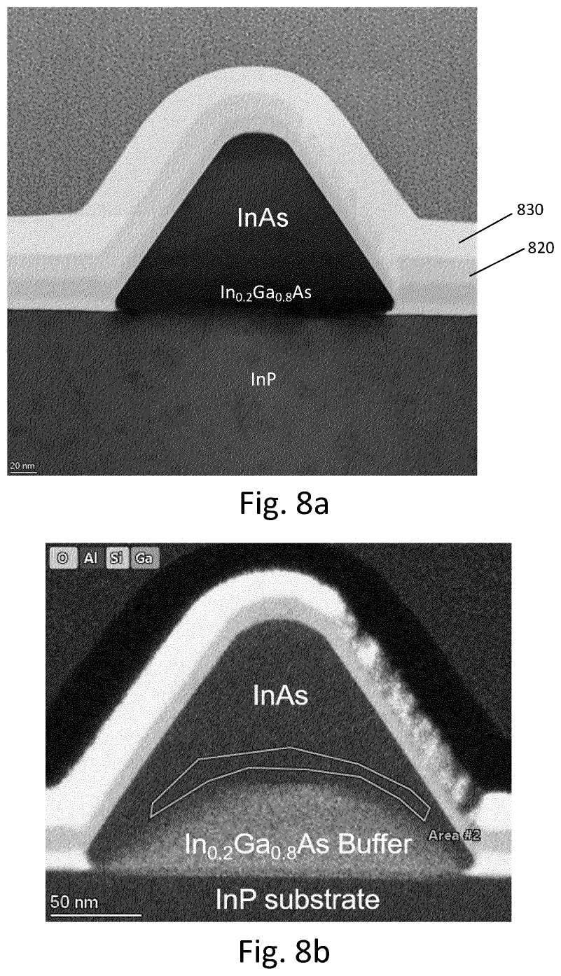

The resultant device was investigated by transmission electron microscopy and energy-dispersive X-ray spectroscopy. The results of these studies are shown in FIGS. 8A and 8B, respectively.

As may be seen, a smooth interface between the metal layer and the semiconductor component was obtained. Similarly, a smooth and well-defined interface between the thin film of metal and the metal oxide layer was obtained. This demonstrates that the methods according to the present disclosure may allow atomically flat and highly uniform thin films to be obtained.

### Example 3

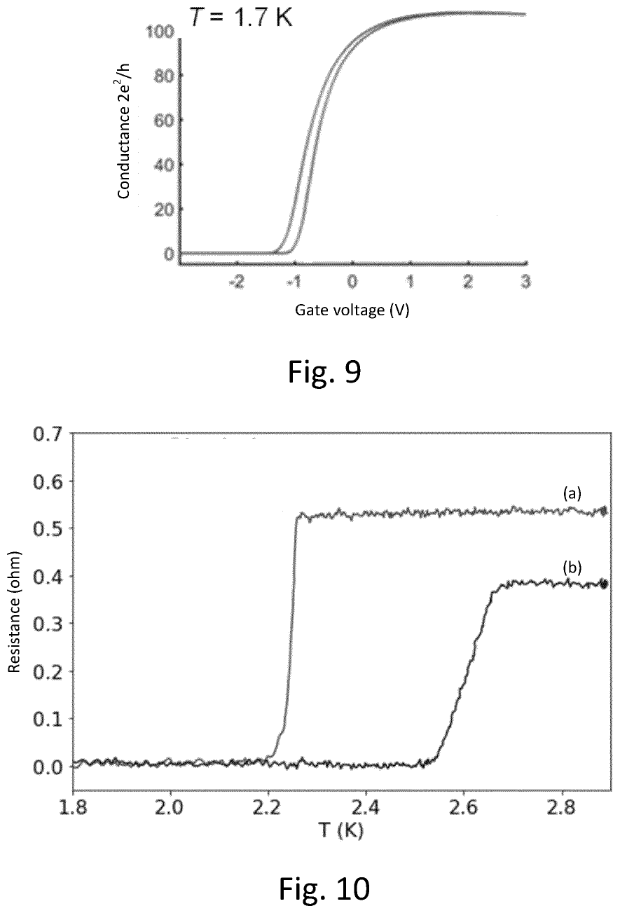

A field-effect transistor, FET, of the type described with reference to FIG. 4 was fabricated using the method of the present disclosure. Changes in the conductance of the channel of the FET as a function of applied gate voltage at 1.7 K were investigated. The results of this investigation are shown in FIG. 9. The two traces shown in FIG. 9 correspond to two voltage sweeps, performed in different directions.

It was found that the source and drain current was pinched off when applying the gate voltage below −1.3 V. Above −1.3 V, the source and drain current dramatically increased showing current on/off switching ratio of 100000. These data demonstrate that an in-situ deposited dielectric works as gate insulator for the FET structure.

### Example 4

Two devices, (a) and (b) were fabricated. Device (a) comprised a single layer of aluminium arranged on a substrate. Device (b) was fabricated according to the method of FIG. 1, and comprised a sandwich structure having two layers of aluminium separated from one another by an aluminium oxide layer.

The resistance of the devices as a function of temperature was investigated, and the results are shown in FIG. 10. The results show that the aluminium layer of device (a) had a critical temperate of approximately 2.2 K, whereas the double aluminium layer structure of device (b) had a higher critical temperature of approximately 2.6 K. These results demonstrate that by forming a multi-layer structure, a superconductor component which is operable at higher temperatures may be obtained.

Other variants or use cases of the disclosed techniques may become apparent to the person skilled in the art once given the disclosure herein. The scope of the disclosure is not limited by the described embodiments but only by the accompanying claims.

1. A method of forming a thin film of material on a surface of a substrate, the substrate comprising a semiconductor, which method comprises:
depositing a thin film of metal on the surface of the substrate;
wherein the deposition is performed in an ultra-high vacuum; and
wherein the substrate is at a temperature of less than or equal to 260 K during the deposition.

2. The method according to claim 1, wherein the metal is selected from a group consisting of aluminium and tantalum.

3. The method according to claim 1, wherein the thin film of metal is deposited using a process selected from a group consisting of molecular beam epitaxy and evaporation.

4. The method according to claim 1, wherein the ultra-high vacuum is an environment having a pressure of less than or equal to 10⁻⁸ Pa.

5. The method according to claim 1, wherein the substrate is in contact with a cold finger during the deposition, the cold finger being at a temperature in the range 110 to 130 K, optionally wherein the cold finger is at a temperature in the range 120 to 130 K.

6. The method according to claim 1, further comprising, after the deposition, oxidising at least a partial thickness of the thin film of metal to form a metal oxide layer, optionally wherein the oxidation comprises fully oxidising the thin film of metal.

7. The method according to claim 6, wherein the metal is aluminium and the oxidation comprises exposing the thin film of metal to oxygen gas, optionally wherein the oxygen gas is at a pressure in the range 0.1 to 10 Pa.

8. The method according to claim 6, further comprising, after the oxidation, performing a further deposition to form a further thin film of metal on the metal oxide layer, wherein the further deposition is performed in an ultra-high vacuum; and wherein the substrate is at a temperature of less than 260 K during the further deposition.

9. The method according to claim 6, wherein the deposition is performed in a deposition vacuum chamber, and the oxidation is performed in an oxidation vacuum chamber, the deposition vacuum chamber and oxidation vacuum chamber being coupled to a buffer chamber via respective valves; and
wherein the method further comprises transferring the substrate between the deposition vacuum chamber to the oxidation vacuum chamber via the buffer chamber.

10. The method according to claim 1, wherein the substrate comprises a wafer of semiconductor material; and wherein the method further comprises, before the deposition, fabricating a semiconductor component on the wafer, optionally wherein fabricating the semiconductor component comprises growing the semiconductor component using molecular beam epitaxy.

11. The method according to claim 1, wherein the substrate comprises a material of Formula 1:
InAsₓSb₁₋ₓ (Formula 1)
where x is in the range 0 to 1.

12. The method according to claim 11, wherein the surface of the substrate is selected from a group consisting of a {100} crystal face, a {111} crystal face, and a {110} crystal face.

13. A device, comprising:
a plurality of thin films of metal; and
a plurality of layers of an oxide of the metal;
wherein the thin films and the layers are arranged in an alternating stack.

14. The device according to claim 13, wherein:
the metal is aluminium; or
the thin films and the layers have a root-mean-square surface roughness in the range 0.1 nm to 0.4 nm.

15. The device according to claim 13, further comprising a semiconductor component, wherein the alternating stack is arranged on the semiconductor component.

16. The method of claim 7, wherein the oxygen gas is at a pressure of 0.5 to 1.5 Pa.

17. The method of claim 8, wherein the method further comprises, after the further deposition, performing an additional further oxidation to form a further metal oxide layer.

18. The method of claim 11, wherein the substrate comprises indium arsenide.

19. A device manufactured according to the method of claim 1.

20. The device of claim 13, wherein at least one of the plurality of thin films of metal is deposited on a substrate comprising InAsₓSb₁₋ₓ.
